(19) United States
(12) Patent Application Publication
(10) Pub. No.: US 2013/0161708 A1
(43) Pub. Date: Jun. 27, 2013

(54) SEMICONDUCTOR STRUCTURE AND METHOD FOR MANUFACTURING THE SAME

(71) Applicants: Ming-Tsan Peng, Zhongli City (TW); Shih-Tung Cheng, Hsinchu City (TW); Edward Yi Chang, Baoshan Township (TW); Po-Chien Chou, Hsinchu City (TW); Shyr-Long Jeng, Tainan City (TW); Chia-Hua Chang, Taichung City (TW); Tsung-Lin Chen, Taipei City (TW); Jian-Feng Tsai, Kaohsiung City (TW)

(72) Inventors: Ming-Tsan Peng, Zhongli City (TW); Shih-Tung Cheng, Hsinchu City (TW); Edward Yi Chang, Baoshan Township (TW); Po-Chien Chou, Hsinchu City (TW); Shyr-Long Jeng, Tainan City (TW); Chia-Hua Chang, Taichung City (TW); Tsung-Lin Chen, Taipei City (TW); Jian-Feng Tsai, Kaohsiung City (TW)

(73) Assignee: INDUSTRIAL TECHNOLOGY RESEARCH INSTITUTE, HSINCHU (TW)

(21) Appl. No.: 13/606,447

(22) Filed: Sep. 7, 2012

(30) Foreign Application Priority Data
Dec. 27, 2011 (TW) 100149018

(51) Int. Cl. H01L 29/78; H01L 21/58

(52) U.S. Cl. 257/288; 438/126; 257/E29.242; 257/E21.505

(57) ABSTRACT

A semiconductor structure and a method for manufacturing the same are provided. The semiconductor structure includes a substrate, a die and a medium. The substrate has an upper substrate surface. The substrate has a trench extended downward from the upper substrate surface. The trench has a side trench surface. The die is in the trench. The die has a lower die surface and a side die surface. The lower die surface is below the upper substrate surface. A part of the trench between the side trench surface and the side die surface is filled with the medium.

This application claims the benefit of Taiwan application Serial No. 100149018, filed Dec. 27, 2011, the disclosure of which is incorporated by reference herein in its entirety.

### BACKGROUND

1. Technical Field

The disclosure relates in general to a semiconductor structure and a method for manufacturing the same, and more particularly to package structure and a method for manufacturing the same.

2. Description of the Related Art

In semiconductor technology, III-V transistors, such as the GaN high electron mobility transistors (GaN HEMT), having high conduction electron density, high electron mobility and wide energy gap, are capable of significantly reducing the on-resistance RDS (on) for elements under a specified reverse voltage, and are suitable elements for manufacturing electronic products requiring high frequency, high power and high efficiency. Therefore, the III-V family transistors, particularly the GaN HEMT, have gradually become the front and center in the semiconductor technology. However, the existing packaging technology still faces the problem of poor dissipation.

### SUMMARY

According to one embodiment, a semiconductor structure is provided. The semiconductor structure includes a substrate, a die and a medium. The substrate has an upper substrate surface. The substrate has a trench extended downward from the upper substrate surface. The trench has a side trench surface. The die is in the trench. The die has a lower die surface and a side die surface. The lower die surface is below the upper substrate surface. A part of the trench between the side trench surface and the side die surface is filled with the medium.

According to another alternative embodiment, a method for manufacturing a semiconductor structure is provided. The method includes following steps. A substrate having an upper substrate surface is provided. A trench extended downward from the upper substrate surface into the substrate is formed. The trench has a side trench surface. A die having a lower die surface and a side die surface is disposed in the trench. The lower die surface is below the upper substrate surface. A part of the trench between the side trench surface and the side die surface is filled with a medium.

The above and other aspects of the disclosure will become better understood with regard to the following detailed description of the preferred but non-limiting embodiment(s). The following description is made with reference to the accompanying drawings.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 shows a cross-sectional view of a semiconductor structure according to one embodiment;

FIG. 2 shows a cross-sectional view of a semiconductor structure according to one embodiment;

FIG. 3 shows a cross-sectional view of a semiconductor structure according to one embodiment;

FIG. 4 shows a cross-sectional view of a semiconductor structure according to one embodiment;

FIG. 5 shows a cross-sectional view of a semiconductor structure according to one embodiment;

FIG. 6 shows a cross-sectional view of a semiconductor structure according to one embodiment.

FIG. 7A and FIG. 7B show analysis of thermal imaging on focal plane of one embodiment.

FIG. 8A and FIG. 8B show analysis of thermal imaging on focal plane of the comparative example.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

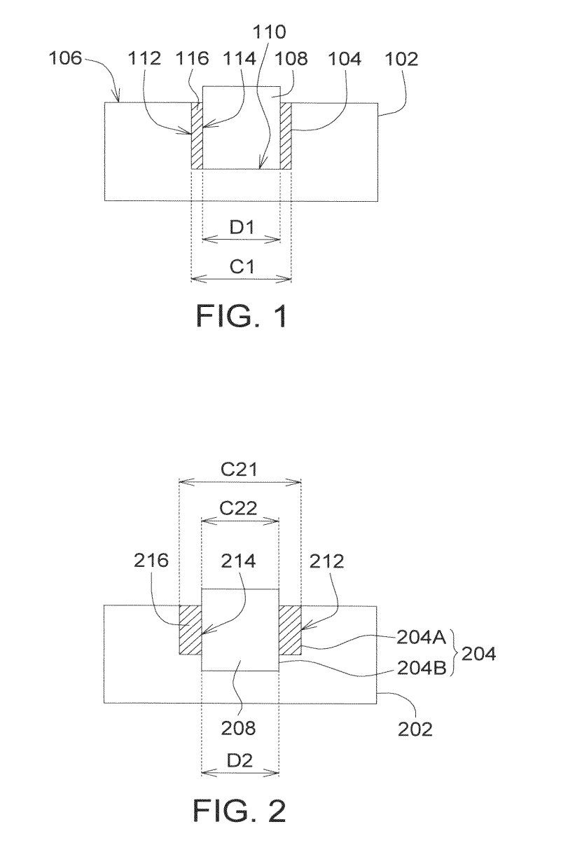

FIG. 1 shows a cross-sectional view of a semiconductor structure according to one embodiment. As indicated in FIG. 1, a substrate 102 has a trench 104. In embodiments, the trench 104 is formed from an upper substrate surface 106 of the substrate 102 and extended downward into the substrate 102. For example, the substrate 102 is a ceramic substrate or a metal substrate such as an aluminum substrate. The trench 104 may be formed by an etching process or an imprinting process.

A die 108 is disposed in the trench 104. The die 108 has a lower die surface 110 and a side die surface 114. The lower die surface 110 is below the upper substrate surface 106. In embodiments, the die 108 has an III-V transistor such as a GaN transistor such as an epitaxial GaN high electron mobility transistor (GaN HEMT). The trench 104 has a side trench surface 112.

In one embodiment, a width C1 of the trench 104 is substantially constant. A width D1 of the die 108 is substantially constant. The width C1 of the trench 104 is larger than the width D1 of the die 108. For example, a value obtained by subtracting the width D1 of the die 108 from the width C1 of the trench 104 is substantially equal to 10% of the width D1 of the die 108. In other embodiments, the width C1 of the trench 104 is substantially equal to the width D1 of the die 108. In other words, a gap between the side trench surface 112 and the side die surface 114 is substantially zero.

A part of the trench 104 between the side trench surface 112 and the side die surface 114 is filled with a medium 116. In details, the medium 116 contacts the side trench surface 112 and the side die surface 114. In an embodiment, the medium 116 is a gas such as air, or a high-thermal-conductivity material such as a metal such as a silver paste. Since heat generated during an operation of the die 108 can be directly transferred toward the medium 116 laterally, an excellent dissipation effect can be achieved.

The design of forming a trench 104 in the substrate 102 makes an alignment for the die 108 easier and more precise. For example, the die 108 can be embedded into the trench 104 by roughly aligning to the trench 104 by a mechanic arm. Thus, an amount of the dies 108 that can be disposed on one single substrate 102 can be increased, that is, the element density is increased. Additionally, a product yield is increased, and a manufacturing cost is reduced.

FIG. 2 shows a cross-sectional view of a semiconductor structure according to one embodiment. The semiconductor structure of FIG. 2 is different from the semiconductor structure of FIG. 1 in that the trench 204 has an upper opening portion 204A and a lower opening portion 204B interconnected with each other. A width C21 of the upper opening portion 204A is larger than a width C22 of the lower opening portion 204B. The width C21 of the upper opening portion 204A and the width C22 of the lower opening portion 204B are constant, respectively. The width C22 of the lower opening portion 204B is substantially equal to the width D2 of the die 208.

The part of the trench 204 between the side trench surface 212 and the side die surface 214 is filled with the medium 216. In details, the medium 216 contacts the side trench surface 212 and the side die surface 214. Since heat generated during an operation of the die 208 can be directly transferred toward the medium 216 laterally, an excellent dissipation effect can be achieved. The design of forming a trench 204 in the substrate 202 makes an alignment for the die 208 easier and more precise. Additionally, a product yield is increased and a manufacturing cost is reduced.

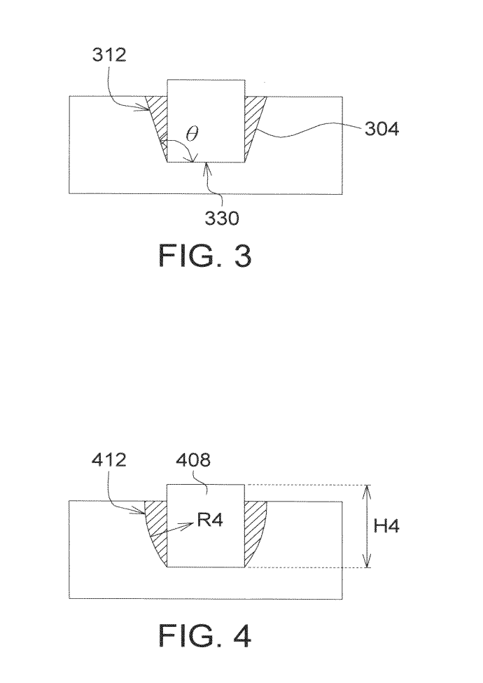

FIG. 3 shows a cross-sectional view of a semiconductor structure according to one embodiment. The semiconductor structure of FIG. 3 is different from the semiconductor structure of FIG. 1 in that the width of the trench 304 is decreased gradually from an upper portion to a lower portion of the trench. The trench 304 has a side trench surface 312 and a bottom trench surface 330. In an embodiment, an angle θ contained between the side trench surface 312 and the bottom trench surface 330 substantially ranges between 110° and 140°. In the embodiment, the side trench surface 312 is substantially a flat surface.

FIG. 4 shows a cross-sectional view of a semiconductor structure according to one embodiment. The semiconductor structure of FIG. 4 is different from the semiconductor structure of FIG. 3 in that the side trench surface 412 is substantially a curved surface having a curvature radius R4. The die 408 has a die height H4. In an embodiment, the die height H4 of the die 408 is smaller than two times of the curvature radius R4 of the side trench surface 412, that is, H4<2*R4. In one embodiment as indicated in FIG. 3, the curvature radius of the flat side trench surface 312 may be regarded as infinite, which is conformed to the disclosed relationship between the die height and curvature radius.

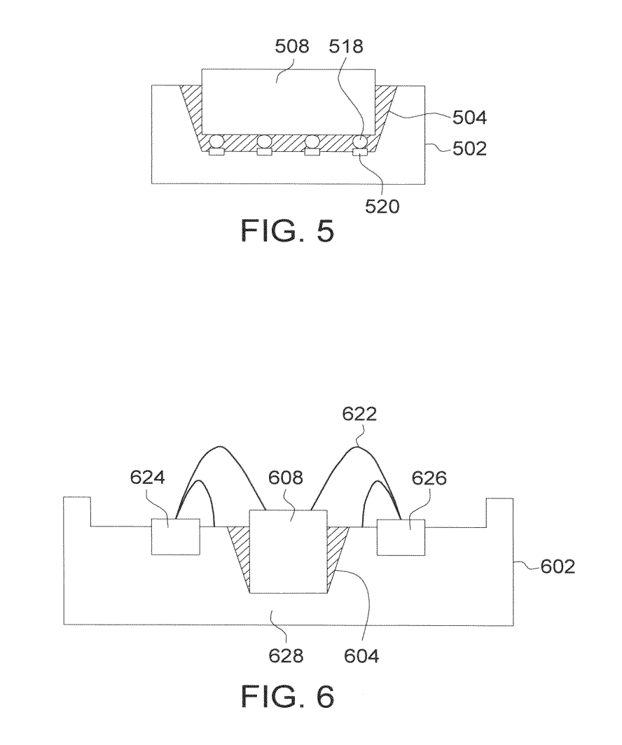

FIG. 5 shows a cross-sectional view of a semiconductor structure according to one embodiment. The semiconductor structure of FIG. 5 is different from the semiconductor structure of FIG. 3 in that the die 508 is bonded to the contact pad 520 in the trench 504 via the solder ball 518 to be electrically connected to the substrate 502.

FIG. 6 shows a cross-sectional view of a semiconductor structure according to one embodiment. The semiconductor structure of FIG. 6 is different from the semiconductor structure of FIG. 3 in that the die 608 in the trench 604 is electrically connected to the gate 624, the drain 626 and the source 628 in the substrate 602 via bonding wires 622.

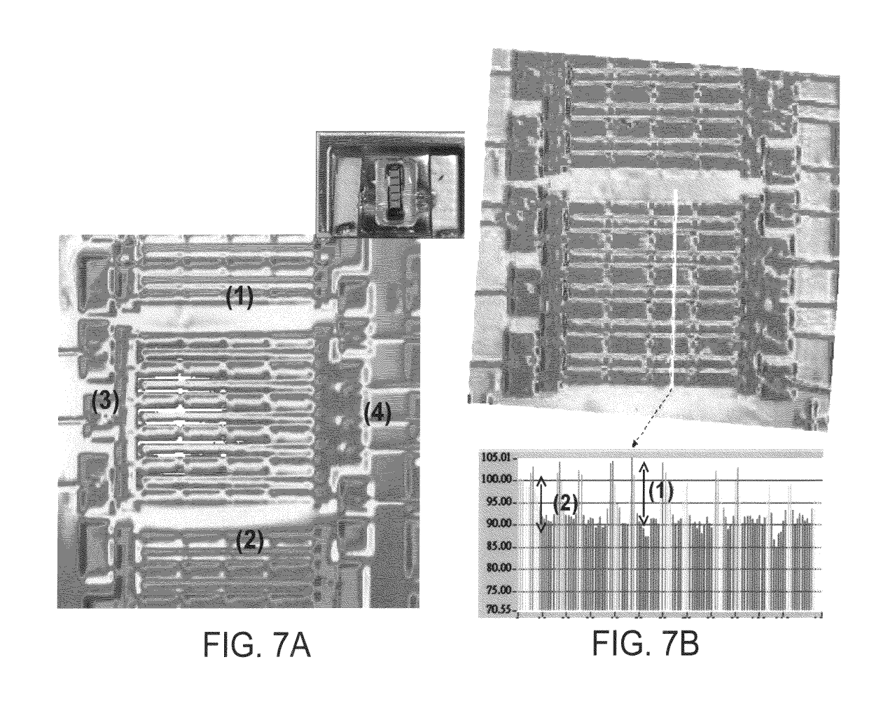

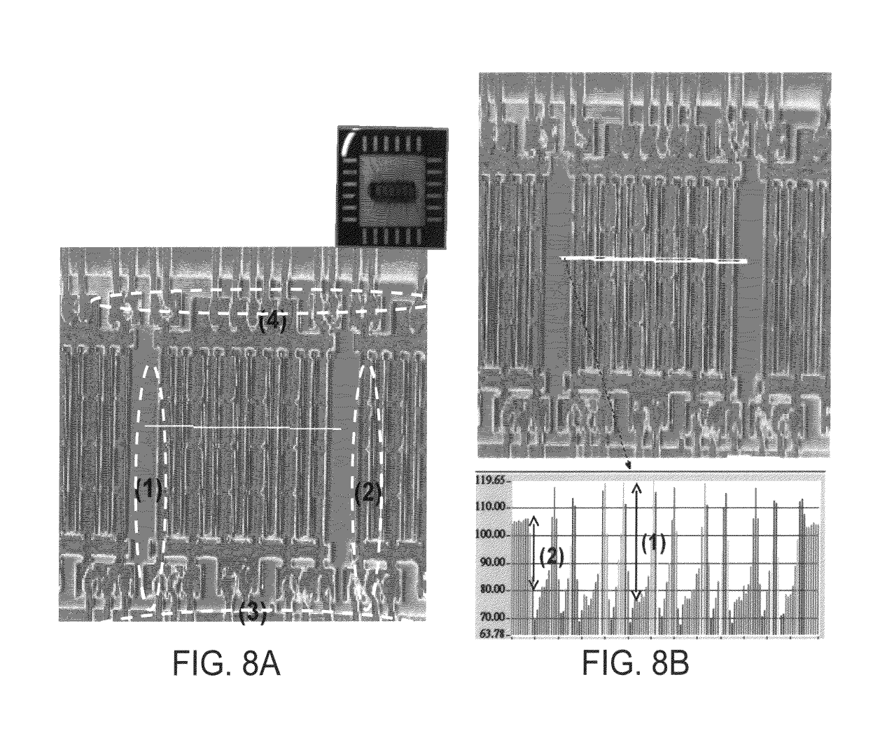

According to the above embodiments, the trench is formed in the substrate, and the die is disposed in the trench, so that heat generated during the operation of the die can be effectively dissipated. The results of heat flow simulation experiment (analysis of thermal imaging on focal plane) show that the dissipation effect of the embodiment (FIG. 7A and FIG. 7B showing that the distribution of high temperature on the one single side of element is improved) in which the die is disposed in the trench in the substrate is higher than that of a comparative example (FIG. 8A and FIG. 8B showing that the abnormal distribution of heat sources demarcated with dotted white lines occurs, the one single side of the element has a high temperature, and the air bridge at the bonding location (gate) of the bonding wires has a high temperature) in which the die is disposed on the upper substrate surface by 67%. The improvement in dissipation is resulted from transferring heat laterally from the side die surface. In addition, the alignment for the die can be precisely controlled. The concepts of embodiments can be applied to various electronic elements such as high-power and small-sized electronic elements.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure, comprising:
a substrate having an upper substrate surface, wherein the substrate has a trench extended downward from the upper substrate surface, and the trench has a side trench surface;
a die disposed in the trench, wherein the die has a lower die surface and a side die surface below the upper substrate surface; and
a medium, wherein a part of the trench between the side trench surface and the side die surface is filled with the medium.

2. The semiconductor structure according to claim 1, wherein the side trench surface has a curvature radius, the die has a die height, the die height is smaller than two times of the curvature radius.

3. The semiconductor structure according to claim 1, wherein the medium contacts the side trench surface and the side die surface.

4. The semiconductor structure according to claim 1, wherein the trench has an upper opening portion and a lower opening portion interconnected to each other, and a width of the upper opening portion is larger than a width of the lower opening portion.

5. The semiconductor structure according to claim 4, wherein the width of the upper opening portion and the width of the lower opening portion respectively are constant.

6. The semiconductor structure according to claim 4, wherein the width of the lower opening portion is substantially equal to a width of the die.

7. The semiconductor structure according to claim 1, wherein a width of the trench is decreased gradually from an upper portion to a lower portion of the trench.

8. The semiconductor structure according to claim 1, wherein a width of the trench is substantially constant.

9. The semiconductor structure according to claim 1, wherein a width of the trench is larger than or substantially equal to a width of the die.

10. The semiconductor structure according to claim 1, further comprising a solder ball and a contact pad, wherein the contact pad is disposed in the trench, and the die is bonded to the contact pad via the solder ball so as to be electrically connected to the substrate.

11. The semiconductor structure according to claim 1, further comprising:
a gate, a drain and a source disposed in the substrate; and
bonding wires electrically connected between the die and the gate, the drain and the source respectively.

12. A method for manufacturing a semiconductor structure, comprising:
providing a substrate having an upper substrate surface;
forming a trench from the upper substrate surface and extended downward into the substrate, wherein the trench has a side trench surface.
disposing a die having a lower die surface and a side die surface in the trench, wherein the lower die surface is below the upper substrate surface; and
filling a part of the trench between the side trench surface and the side die surface with a medium.
